(19) United States
(12) Patent Application Publication
(10) Pub. No.: US 2016/0109775 A1
(43) Pub. Date: Apr. 21, 2016

(54) DISPLAY SUBSTRATE AND DISPLAY PANEL COMPRISING THE SAME

(71) Applicant: SAMSUNG DISPLAY CO., LTD., Yongin-City (KR)

(72) Inventor: Myungwook CHOI, Cheonan-si (KR)

(21) Appl. No.: 14/717,565

(22) Filed: May 20, 2015

(30) Foreign Application Priority Data
Oct. 17, 2014 (KR) 10-2014-0140827

(51) Int. Cl. G02F 1/1362; H01L 27/12; G02F 1/1368

(52) U.S. Cl. CPC G02F 1/136286; G02F 1/1368; H01L 27/124

(57) ABSTRACT

A display substrate, including a first substrate; a gate line on the first substrate; a data line intersecting the gate line; a thin film transistor at an intersecting point of the gate line and the data line; a pixel electrode electrically connected to the thin film transistor; a first storage line spaced apart from and parallel to the gate line; and a second storage line perpendicularly extending from the first storage line, the thin film transistor including a gate electrode connected to the gate line and including a protrusion protruding toward the second storage line, a source electrode connected to the data line, and a drain electrode connected to the pixel electrode, and the second storage line having a concave portion corresponding to the protrusion.

### CROSS-REFERENCE TO RELATED APPLICATION

Korean Patent Application No. 10-2014-0140827, filed on Oct. 17, 2014, in the Korean Intellectual Property Office, and entitled: “Display Substrate and Display Panel Comprising The Same,” is incorporated by reference herein in its entirety.

### BACKGROUND

1. Field

Provided is a display substrate.

2. Description of the Related Art

A liquid crystal display (LCD) is a type of flat panel display (FPD). An LCD may include two substrates with electric field generating electrodes formed thereon and a liquid crystal layer interposed therebetween. Upon applying voltage to the electrodes, liquid crystal molecules of the liquid crystal layer are rearranged, and an amount of transmitted light may be adjusted.

### SUMMARY

Embodiments may be realized by providing a display substrate, including a first substrate; a gate line on the first substrate; a data line intersecting the gate line; a thin film transistor at an intersecting point of the gate line and the data line; a pixel electrode electrically connected to the thin film transistor; a first storage line spaced apart from and parallel to the gate line; and a second storage line perpendicularly extending from the first storage line, the thin film transistor including a gate electrode connected to the gate line and including a protrusion protruding toward the second storage line, a source electrode connected to the data line, and a drain electrode connected to the pixel electrode, and the second storage line having a concave portion corresponding to the protrusion.

The protrusion may have a smaller width than the second storage line.

The protrusion may have a width tapering in a direction toward the second storage line.

The protrusion may have the shape of a triangle, a trapezoid, or a semicircle.

The protrusion may partially overlap the concave portion.

The concave portion may have a same shape as the protrusion.

The concave portion may have the shape of a triangle, a trapezoid, or a semicircle.

The second storage line may overlap the data line or the pixel electrode.

Embodiments may be realized by providing a display panel, including a first substrate; a gate line on the first substrate; a data line intersecting the gate line; a thin film transistor at an intersecting point of the gate line and the data line; a pixel electrode electrically connected to the thin film transistor; a first storage line spaced apart from and parallel to the gate line; a second storage line perpendicularly extending from the first storage line; a second substrate opposed to the first substrate; and a liquid crystal layer between the first substrate and the second substrate, the thin film transistor including a gate electrode connected to the gate line and including a protrusion protruding toward the second storage line, a source electrode connected to the data line, and a drain electrode connected to the pixel electrode, and the second storage line having a concave portion corresponding to the protrusion.

The protrusion may have a smaller width than the second storage line.

The protrusion may have a width tapering in a direction toward the second storage line.

The protrusion may have the shape of a triangle, a trapezoid, or a semicircle.

The protrusion may partially overlap the concave portion.

The concave portion may have a same shape as the protrusion.

The concave portion may have the shape of a triangle, a trapezoid, or a semicircle.

The second storage line may overlap the data line or the pixel electrode.

The display panel may further include a common electrode on the second substrate.

### BRIEF DESCRIPTION OF THE DRAWINGS

Features will become apparent to those of skill in the art by describing in detail exemplary embodiments with reference to the attached drawings in which:

FIG. 1 illustrates a block diagram of a display device according to one embodiment;

FIG. 2 illustrates an equivalent circuit diagram of a configuration of a display panel and a pixel illustrated in FIG. 1;

FIG. 3 illustrates a plan view of a pixel of a display panel according to one embodiment;

FIG. 4 illustrates a cross-sectional view taken along line I-I′ illustrated in FIG. 3;

FIG. 5 illustrates an enlarged plan view of part A of FIG. 3;

FIG. 6 illustrates a plan view of a pixel of a display panel according to an embodiment;

FIG. 7 illustrates an enlarged plan view of part B of FIG. 6;

FIG. 8 illustrates a plan view of a pixel of a display panel according to an embodiment; and

FIG. 9 illustrates an enlarged plan view of part C of FIG. 8.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

Throughout the specification, when an element is referred to as being “connected” to another element, the element is “directly connected” to the other element, or “electrically connected” to the other element with one or more intervening elements interposed therebetween. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms used herein (including technical and scientific terms) have the same meaning as commonly understood by those skilled in the art. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

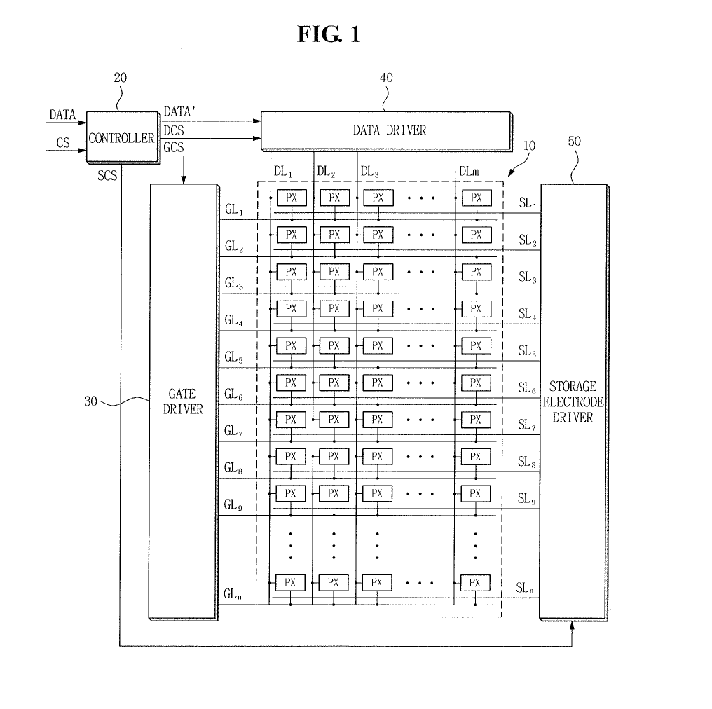

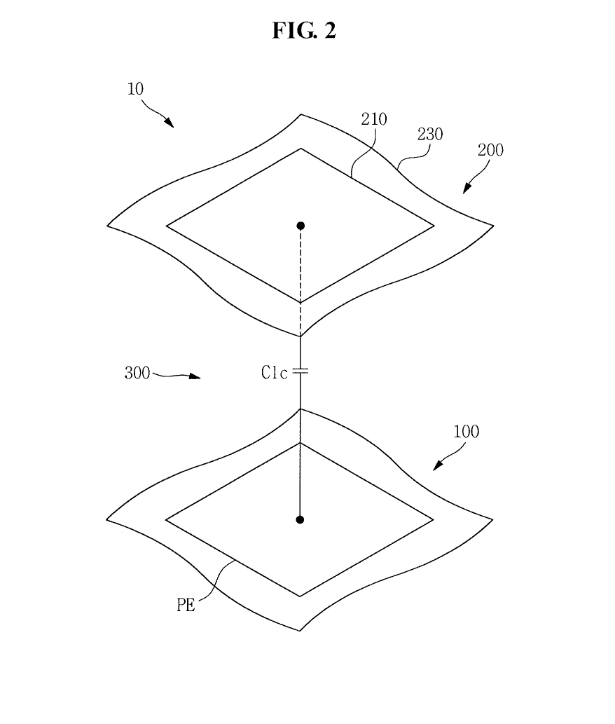

FIG. 1 illustrates a block diagram of a display device according to one embodiment. FIG. 2 illustrates an equivalent circuit diagram of a configuration of a display panel and a pixel illustrated in FIG. 1.

Referring to FIGS. 1 and 2, the display device according to one embodiment may include a display panel 10 including a plurality of pixels PXs, a controller 20 configured to process externally applied image signal DATA and control signal CS to output a variety of signals, a gate driver 30 configured to supply a gate signal to gate lines GL1˜GLn connected to the pixels PXs, and a data driver 40 configured to supply a data voltage to data lines DL1˜DLm connected to the pixels PXs, and a storage driver 50 configured to supply a storage voltage to storage lines SL1˜SLn connected to the pixels PXs.

The display panel 10 may include the plurality of gate lines GL1˜GLn configured to supply the gate signal in a row direction, the plurality of storage lines SL1˜SLn configured to supply the storage voltage in a row direction, the plurality of data lines DL1˜DLm configured to supply the data voltage in a column direction, and the plurality of pixels PXs arranged in a matrix form at intersecting points of the gate and data lines.

The display panel 10 may include separately formed first substrate 100 and second substrate 200, which may be disposed to face the first substrate 100, and a liquid crystal layer 300 interposed therebetween.

In an embodiment, a pixel electrode PE may be disposed on the first substrate 100 and a color filter 210 and a common electrode 230 may be disposed on the second substrate 200. In an embodiment, the pixel electrode PE, the common electrode 230, and the liquid crystal layer 300 may together form a liquid crystal capacitor C1c. In an embodiment, the color filter 210 may be formed on the first substrate 100.

The controller 20 may be configured to output, based on the externally supplied image signal DATA, a corrected image signal DATA′ to the data driver 40. The controller 20 may apply, based on the externally supplied control signal CS, a gate control signal GCS to the gate driver 30, a data control signal DCS to the data driver 40, and a storage control signal SCS to the storage driver 50. For example, the control signal CS may be a timing signal, such as a vertical synchronization signal Vsync, a horizontal synchronization signal Hsync, a clock signal CLK, and a data enable signal DE. The image signal DATA may be a digital signal expressing a gray level of light emitted from the pixel PX.

The gate driver 30 may be configured to receive the gate control signal GCS from the controller 20 to generate a gate signal and supply the gates signal to the pixels PXs respectively connected to the plurality of gate lines GL1˜GLn. As the gate signals are sequentially inputted to the pixel PX, the data voltages may be sequentially applied to the pixel PX.

The data driver 40 may be configured to receive the data control signal DCS and the corrected image signal DATA′ from the controller 20 and supply, in response to the data control signal DCS, a data voltage corresponding to the corrected image signal DATA′ to the pixels PXs respectively connected to the plurality of data lines DL1˜DLm.

The storage driver 50 may be configured to receive the storage control signal SCS from the controller 20 to generate a storage voltage and provide the storage voltage to the plurality of storage lines SL1˜SLn.

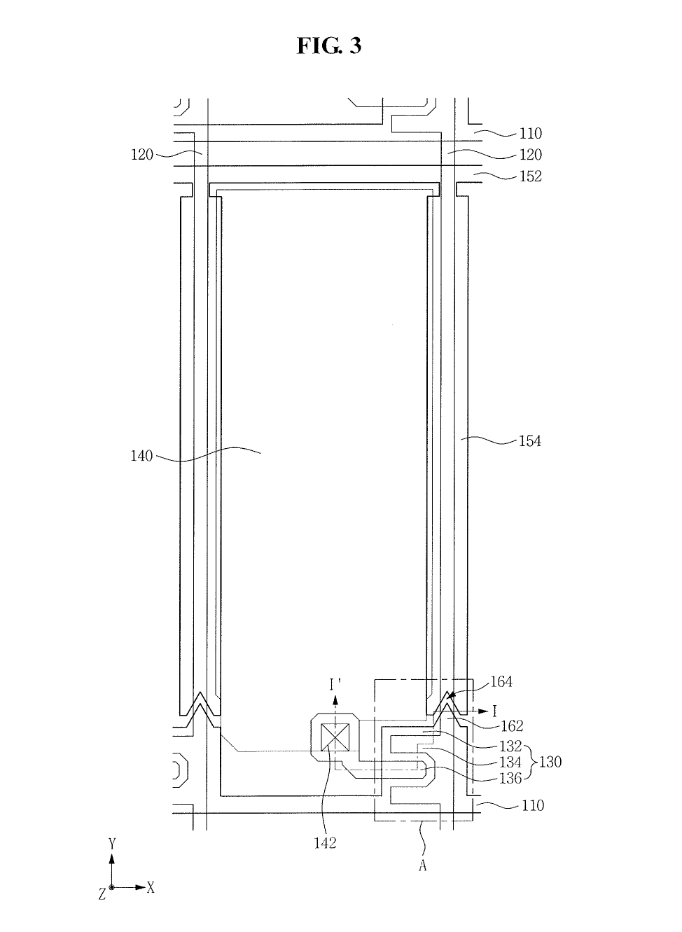

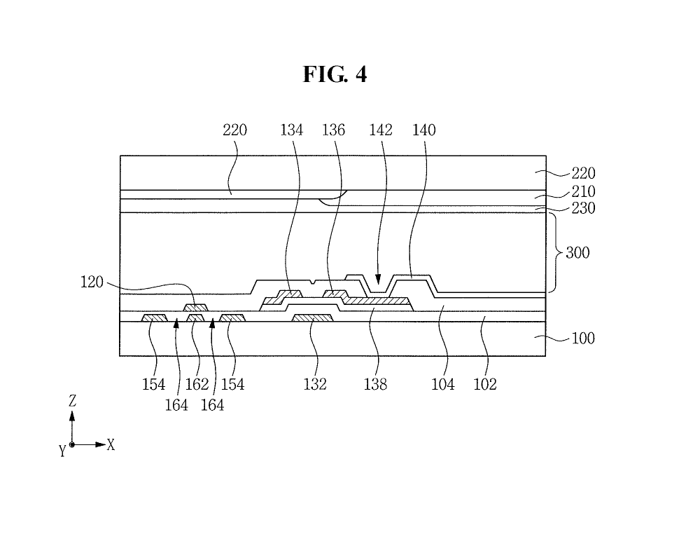

FIG. 3 illustrates a plan view of a pixel of a display panel according to one embodiment. FIG. 4 illustrates a cross-sectional view taken along line I-I′ illustrated in FIG. 3.

Referring to FIGS. 3 and 4, the display substrate according to one embodiment may include the first substrate 100, a gate line 110 on the first substrate 100, a data line 120 intersecting the gate line 110, e.g., the data line 120 may be orthogonal to the gate line 110, a thin film transistor (TFT) 130 disposed at intersecting points of the gate and data lines 110 and 120, a pixel electrode 140 electrically connected to the TFT 130, a first storage line 152 spaced apart from and parallel to the gate line 110, e.g., in a horizontal or Y direction, and a second storage line 154 perpendicularly extending from the first storage line 152, e.g., in the horizontal or Y direction.

The first substrate 100 may include transparent glass or plastic and may be provided in a flat-panel type or a curved type having a predetermined radius of curvature.

The gate lines 110 may be provided in plural on the first substrate 100 and spaced apart from each other in a horizontal direction, e.g., a Y direction. The gate line 110 may include, for example, aluminum (Al)-based metal such as aluminum or an aluminum alloy, silver (Ag)-based metal such as silver or a silver alloy, copper (Cu)-based metal such as copper or a copper alloy, molybdenum (Mo)-based metal such as molybdenum or a molybdenum alloy, chromium (Cr), tantalum (Ta) and titanium (Ti). In some embodiments, the gate line 110 may have a multi-layer structure including at least two conductive layers that have physical properties different from each other.

The data lines 120 may be provided in plural and spaced apart from each other in a vertical direction, e.g., an X direction to intersect the gate line 110, e.g., the data lines 120 may be orthogonal to the gate line 110. The data lines 120 may be insulated from the gate lines 110 by a gate insulating layer 102. The data line 120 may include, for example, refractory metal, such as molybdenum, chromium, tantalum and titanium or a metal alloy thereof. In some embodiments, the data line 120 may have a multi-layer structure including a refractory metal layer and a low-resistance conductive layer.

The TFT 130 may include a gate electrode 132 connected to the gate line 110, a source electrode 134 connected to the data line 120, and a drain electrode 136 connected to the pixel electrode 140.

The gate electrode 132 may be insulated from the source and drain electrodes 134 and 136 by the gate insulating layer 102. A semiconductor layer 138 may be disposed between the gate insulating layer 102 and the source electrode 134 and between the gate insulating layer 102 and the drain electrode 136. A protection layer 104 including an organic insulating material and an inorganic insulating material may be disposed on the source electrode 134 and the drain electrode 136.

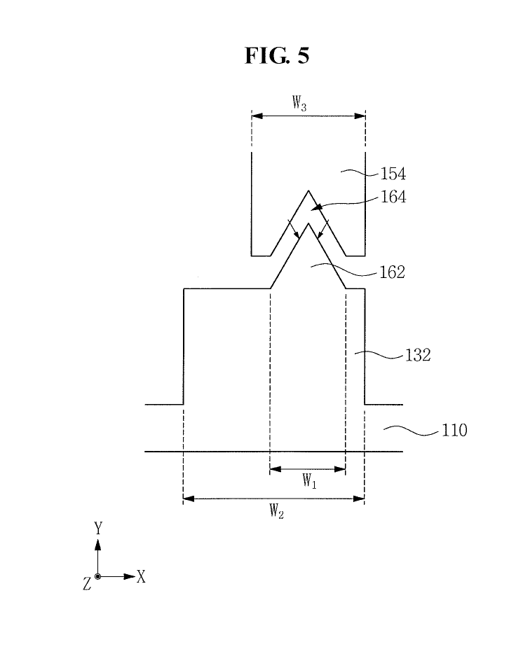

The gate electrode 132 may extend from the gate line 110 and may be integrally formed along with the gate line 100. The gate electrode 132 may have a protrusion 162 that protrudes from a side thereof, e.g., an upper side thereof, toward the second storage line 154. The protrusion 162 is described below in detail with reference to FIG. 5.

The pixel electrode 140 may be disposed on the protection layer 104 and connected to the drain electrode 136 through a contact hole 142. The pixel electrode 140 may include materials imparted with optical transparency and electric conductivity.

An alignment layer may be disposed on the pixel electrode 140. The alignment layer may be a vertical alignment layer or an alignment layer optically aligned using a photopolymer material. The photopolymer material may be a reactive monomer or a reactive mesogen.

In an embodiment, the first and second storage lines 152 and 154 may be disposed on the same layer as the gate line 110. In an embodiment, the first storage line 152 may be spaced apart from the gate line 110, e.g., in the horizontal or Y direction, and may be substantially parallel thereto. In an embodiment, the second storage line 154 may perpendicularly extend from the first storage line 152, e.g., in the horizontal or Y direction. In an embodiment, the first and second storage lines 152 and 154 may be integrally formed together.

The second storage line 154 may overlap the data line 120 or the pixel electrode 140. The second storage line 154 may overlap the data line 120 with the gate insulating layer 102 interposed therebetween, and a fringe field from the data line 120 to the pixel electrode 140 and light leakage between the data line 120 and the pixel electrode 140 may be prevented.

The second storage line 154 may have a concave portion 164 corresponding to the protrusion 162 of the gate electrode 132, e.g., in the horizontal or Y direction. The concave portion 164 is described below in detail with reference to FIG. 5.

The second substrate 200 may include transparent glass or plastic and may be provided in a flat-panel type or a curved type having a predetermined radius of curvature corresponding to the first substrate 100.

In an embodiment, a color filter 210, a black matrix 220, and a common electrode 230 may be disposed on the second substrate 200. In some embodiment, the color filter 210, the black matrix 220, and the common electrode 230 may be disposed on the first substrate 200.

In an embodiment, the color filter 210 may display one of three primary colors of red, green, and blue. In some embodiments, the color filter 210 may display one of cyan, magenta, yellow, and white colors.

The black matrix 220 may be provided along the gate and data lines 110 and 120 and the TFT 130 to prevent light leakage. The black matrix 220 may include metal oxides, such as CrO and CrOₓ, or a black resin.

The common electrode 230 may be integrally disposed over an entire surface of the second substrate 200 to cover the color filter 210 and the black matrix 220. A predetermined pattern may be defined on the common electrode 230. The common electrode 230 may include materials imparted with optical transparency and electrical conductivity.

An alignment layer may be disposed on the common electrode 230. The alignment layer may be a vertical alignment layer or an alignment layer optically aligned using a photopolymer material. The photopolymer material may be a reactive monomer or a reactive mesogen.

FIG. 5 illustrates an enlarged plan view of part A of FIG. 3.

Referring to FIG. 5, the protrusion 162 may protrude from a side of the gate electrode 132, e.g., the upper side of the gate electrode 132, to the second storage line 154. The concave portion 164 may be a dent or may be dented from a side of the second storage line 154, e.g., a lower side of the second storage line 154, in a same direction as a protruding direction of the protrusion 162, e.g., the horizontal or Y direction.

In an embodiment, a width W1 of the protrusion 162 may be smaller than a width W3 of the second storage line 154 and a width W2 of the gate electrode 132 may be greater than the width W3 of the second storage line 154. In an embodiment, the protrusion 162 and the gate electrode 132 may have the same width in accordance with the size and disposition of the pixel electrode 140. Likewise, the gate electrode 132 and the second storage line 154 may have the same width in accordance with the size and disposition of the pixel electrode 140.

In an embodiment, the protrusion 162 may have a width tapering in a direction toward the second storage line 154, and electric field generated between the gate electrode 132 and the second storage line 154 may be efficiently controlled.

In one embodiment, the protrusion 162 may be a triangle in shape with a width tapering in a direction toward the second storage line 154. In some embodiments, the protrusion 162 may be a polygon, such as a trapezoid or a semicircle, in shape.

The protrusion 162 may partially overlap with the concave portion 164, and electric field generated between the gate electrode 132 and the second storage line 154 may be controlled to, e.g., contained in, an area of the concave portion 164. In an embodiment, the protrusion 162 may be bilaterally symmetric, and electric field generated between the gate electrode 132 and the second storage line 154 may be efficiently controlled.

Electric field generated between the gate electrode 132 and the second storage line 154 may be controlled in arrow directions (shown in FIG. 5) in the area of the concave portion 164 and electric fields generated in the arrow directions (shown in FIG. 5) may cancel each other out. As a result, bright line defects caused at an edge portion of the pixel along the gate and date lines 110 and 120 may be prevented.

The concave portion 164 may have a width tapering in a protruding direction of the protrusion 162, as does the protrusion 162. In an embodiment, the concave portion 164 may have the same shape as the protrusion 162. In some embodiments, the concave portion 164 may have a shape with a width tapering in a protruding direction of the protrusion 162 but different from that of the protrusion 162. In one embodiment, the concave portion 164 may be a triangle in shape with a width tapering in a protruding direction of the protrusion 162.

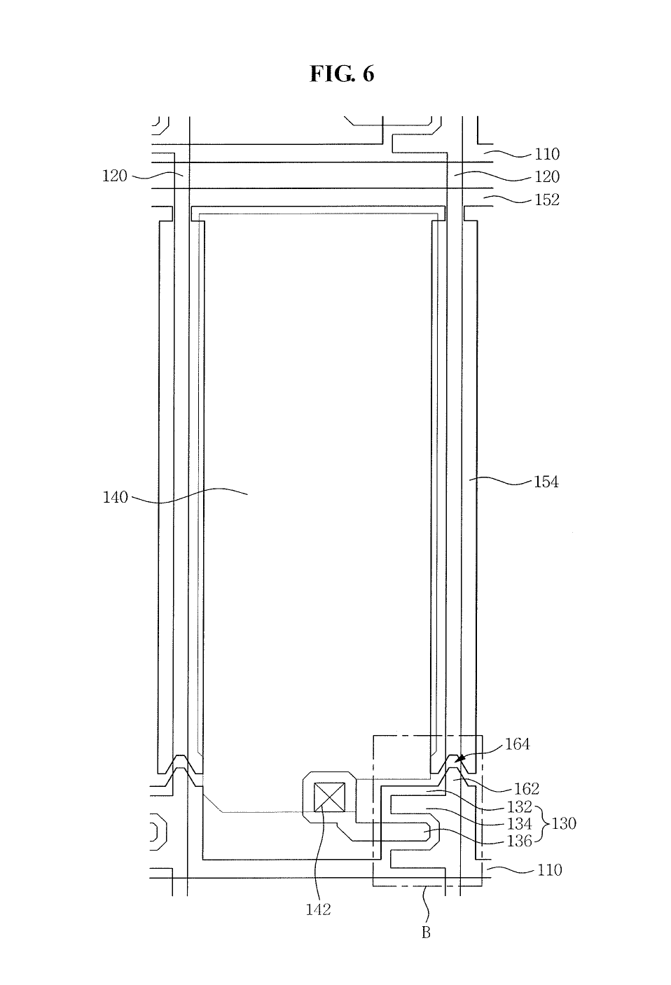

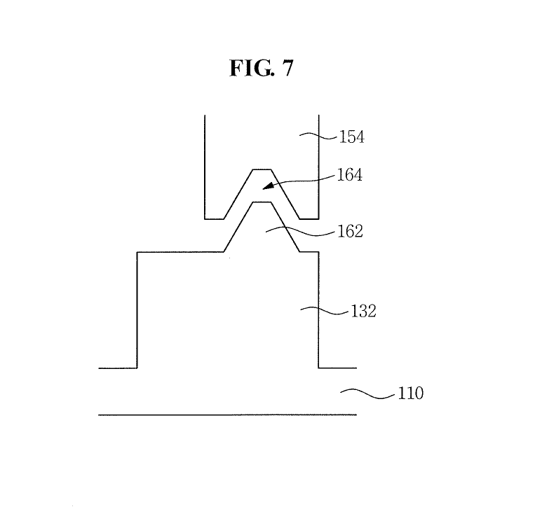

FIG. 6 illustrates a plan view of a pixel of a display panel according to an embodiment. FIG. 7 illustrates an enlarged plan view of part B of FIG. 6.

Referring to FIGS. 6 and 7, the display substrate according to an embodiment may be the same as the display substrate illustrated in FIG. 3, except for shapes of the protrusion 162 and the concave portion 164, and repeated description will not be provided for brevity.

The protrusion 162 may have a width tapering toward the second storage line 154 and may be a bilaterally symmetric trapezoid in shape. The concave portion 164 may have a width tapering in a protruding direction of the protrusion 162 and may be a trapezoid in shape, as is the protrusion 162.

The protrusion 162 may partially overlap the concave portion 164, and electric field generated between the gate electrode 132 and the second storage line 154 may cancel each other out in the area of the concave portion 164.

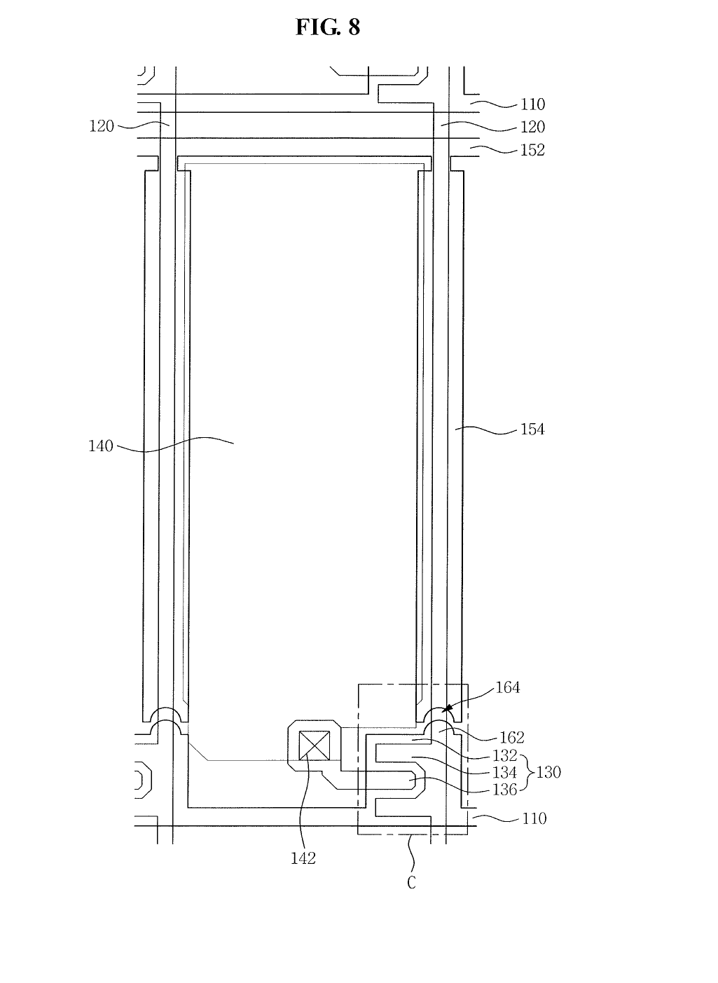

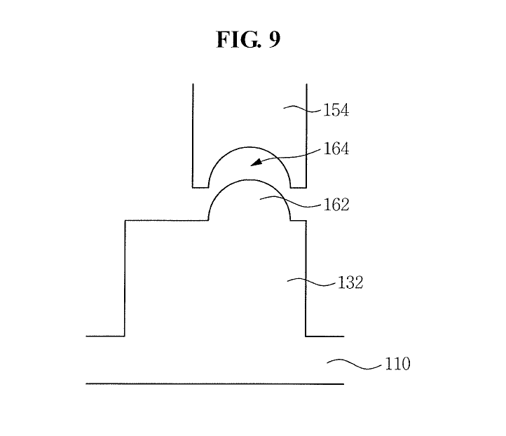

FIG. 8 illustrates a plan view of a pixel of a display panel according to an embodiment. FIG. 9 illustrates an enlarged plan view of part C of FIG. 3.

Referring to FIGS. 8 and 9, the display substrate according to an embodiment may be the same as the display substrate illustrated in FIG. 3, except for shapes of the protrusion 162 and the concave portion 164, and repeated description will not be provided for brevity.

The protrusion 162 may have a width tapering toward the second storage line 154 and may be a bilaterally symmetric semicircle in shape. The concave portion 164 may have a width tapering in a protruding direction of the protrusion 162 and may be a semicircle in shape, as is the protrusion 162.

The protrusion 162 may partially overlap the concave portion 164, and electric field generated between the gate electrode 132 and the second storage line 154 may cancel each other out in the area of the concave portion 164.

By way of summation and review, embodiments are directed to a display substrate and to a display panel including the display substrate. According to embodiments, a bright line defect, which may be caused at an edge portion of a pixel by electric field generated between a gate electrode and a storage line, e.g., of a thin film transistor, may be prevented or efficiently reduced, and picture quality may be improved.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A display substrate, comprising:
a first substrate;
a gate line on the first substrate;
a data line intersecting the gate line;
a thin film transistor at an intersecting point of the gate line and the data line;
a pixel electrode electrically connected to the thin film transistor;
a first storage line spaced apart from and parallel to the gate line; and
a second storage line perpendicularly extending from the first storage line, the thin film transistor including a gate electrode connected to the gate line and including a protrusion protruding toward the second storage line, a source electrode connected to the data line, and a drain electrode connected to the pixel electrode, and
the second storage line having a concave portion corresponding to the protrusion.

2. The display substrate as claimed in claim 1, wherein the protrusion has a smaller width than the second storage line.

3. The display substrate as claimed in claim 1, wherein the protrusion has a width tapering in a direction toward the second storage line.

4. The display substrate as claimed in claim 1, wherein the protrusion has the shape of a triangle, a trapezoid, or a semicircle.

5. The display substrate as claimed in claim 1, wherein the protrusion partially overlaps the concave portion.

6. The display substrate as claimed in claim 1, wherein the concave portion has a same shape as the protrusion.

7. The display substrate as claimed in claim 1, wherein the concave portion has the shape of a triangle, a trapezoid, or a semicircle.

8. The display substrate as claimed in claim 1, wherein the second storage line overlaps the data line or the pixel electrode.

9. A display panel, comprising:
a first substrate;
a gate line on the first substrate;
a data line intersecting the gate line;
a thin film transistor at an intersecting point of the gate line and the data line;
a pixel electrode electrically connected to the thin film transistor;
a first storage line spaced apart from and parallel to the gate line;
a second storage line perpendicularly extending from the first storage line;
a second substrate opposed to the first substrate; and
a liquid crystal layer between the first substrate and the second substrate,
the thin film transistor including a gate electrode connected to the gate line and including a protrusion protruding toward the second storage line, a source electrode connected to the data line, and a drain electrode connected to the pixel electrode, and
the second storage line having a concave portion corresponding to the protrusion.

10. The display panel as claimed in claim 9, wherein the protrusion has a smaller width than the second storage line.

11. The display panel as claimed in claim 9, wherein the protrusion has a width tapering in a direction toward the second storage line.

12. The display panel as claimed in claim 9, wherein the protrusion has the shape of a triangle, a trapezoid, or a semicircle.

13. The display panel as claimed in claim 9, wherein the protrusion partially overlaps the concave portion.

14. The display panel as claimed in claim 9, wherein the concave portion has a same shape as the protrusion.

15. The display panel as claimed in claim 9, wherein the concave portion has the shape of a triangle, a trapezoid, or a semicircle.

16. The display panel as claimed in claim 9, wherein the second storage line overlaps the data line or the pixel electrode.

17. The display panel as claimed in claim 9, further comprising a common electrode on the second substrate.
